(19) United States
(12) Patent Application Publication
(10) Pub. No.: US 2025/0313434 A1
(43) Pub. Date: Oct. 9, 2025

(54) OVERHEAD HOIST TRANSPORT AND ITS VOICE CONTROL SYSTEM AND METHOD

(71) Applicant: NANYA TECHNOLOGY CORPORATION, New Taipei city (TW)

(72) Inventors: Po-Hsien CHEN, New Taipei City (TW); Zheng-Xun YANG, New Taipei City (TW)

(21) Appl. No.: 18/628,693

(22) Filed: Apr. 6, 2024

(51) Int. Cl. B66C 13/40; B66C 19/00; G10L 17/22; H01L 21/677

(52) U.S. Cl. CPC B66C 13/40; G10L 17/22; H01L 21/67733; B66C 19/00

(57) ABSTRACT

A voice control method of an overhead hoist transport (OHT) includes some steps as follows. An ambient sound is received. A determination is made as whether the ambient sound is any of control commands for controlling an OHT. If the ambient sound is one of the control commands for controlling the OHT, a determination is made as whether the control command is for immediately stopping the OHT. If the control command is for immediately stopping the OHT, the OHT is immediately stopped according to the control command, otherwise, a determination is made as whether a voiceprint pattern of the ambient sound matches a preset voiceprint pattern of an authorized user. If the voiceprint pattern matches the preset voiceprint pattern, the OHT is instructed to perform a move corresponding to the control command.

### BACKGROUND

### Field of Disclosure

The present disclosure relates to an overhead hoist transport. More particularly, the present disclosure relates to an overhead hoist transport, a voice control system and a voice control method of the overhead hoist transport in emergency.

### Description of Related Art

Generally, overhead hoist transports may be used in a semiconductor automated logistics system for transporting materials in a production site. More specifically, an overhead hoist transport (OHT) can be assigned by a control center to deliver different materials in the production site, and the control center remotely controls the OHT through wireless fashions. Once any abnormality occurs on the OHT, personnel will be sent to the production site for troubleshooting with a remote controller (e.g., IR or WiFi communication).

However, due to various signal interference factors in the production site, once the abnormality occurs on the OHT, the OHT cannot be timely controlled by the remote controller, thereby affecting the production efficiency of the production site and increasing personnel security risks.

Thus, the above-mentioned technology obviously still has inconveniences and defects, which are issues that the industry needs to solve urgently.

### SUMMARY

One aspect of the present disclosure is to provide an overhead hoist transport, and a voice control system and a voice control method of the overhead hoist transport in emergency for solving the difficulties mentioned above in the prior art.

In one embodiment of the present disclosure, a voice control method of an overhead hoist transport (OHT) includes several steps (a) to (f) described as follows. (a) An ambient sound is received. (b) A determination is made as whether the ambient sound is corresponded to one of control commands for controlling the OHT. (c) A determination is made as whether the control command is for immediately stopping the OHT when a determination is made that the ambient sound is corresponded to one of the control commands for controlling the OHT. (d) The OHT is immediately stopped when a determination is made that the one of the control commands is for immediately stopping the OHT. (e) A determination is made as whether a voiceprint pattern of the ambient sound matches a preset voiceprint pattern of an authorized user when a determination is made that the one of the control commands is not for immediately stopping the OHT. (f) The OHT is instructed to perform a move corresponding to the control command when a determination is made that the voiceprint pattern matches the preset voiceprint pattern.

In one embodiment of the present disclosure, a voice control system of overhead hoist transport in emergency includes a sound receiving unit, a database unit, a voiceprint extracting unit and a processing unit. The sound receiving unit is configured to receive an ambient sound. The database unit is stored with control commands and a preset voiceprint pattern of an authorized user, and the control commands are respectively used for controlling the OHT. The voiceprint extracting unit is configured to extract a voiceprint pattern from the ambient sound. The processing unit is electrically connected to the sound receiving unit, the database unit and the voiceprint extracting unit. The processing unit is configured to determine whether the ambient sound is one of the control commands for controlling the OHT, determine whether the one of the control commands is for immediately stopping the OHT when a determination is made that the ambient sound is the one of the control commands for controlling the OHT, immediately stop the OHT when a determination is made that the one of the control commands is for immediately stopping the OHT, determine whether the voiceprint pattern of the ambient sound matches a preset voiceprint pattern of an authorized user when a determination is made that the one of the control commands is not for immediately stopping the OHT, and instruct the OHT to perform a move corresponding to the one of the control commands when a determination is made that the voiceprint pattern matches the preset voiceprint pattern.

In one embodiment of the present disclosure, an overhead hoist transport (OHT) includes a housing, a pick-up system, a transmission system, a control circuit portion and a voice control system. The pick-up system is disposed on the housing for picking up an object. The transmission system is disposed on the housing for moving the housing along a rail. The voice control system comprising a sound receiving unit, a database unit, a voiceprint extracting unit and a processing unit, the sound receiving unit that is disposed on the housing for receiving an ambient sound, the database unit that is disposed in the housing and stored with control commands and a preset voiceprint pattern of an authorized user, and each of the control commands is used for controlling the OHT, the voiceprint extracting unit that is disposed in the housing for extracting a voiceprint pattern from the ambient sound, the processing unit that is electrically connected to the sound receiving unit, the database unit, the voiceprint extracting unit and the control circuit portion. The processing unit is configured to determine whether the ambient sound is one of the control commands for controlling the OHT, determine whether the one of the control commands is for immediately stopping the transmission system when a determination is made that the ambient sound is the one of the control commands for controlling the OHT, immediately stop the transmission system when a determination is made that the one of the control commands is for immediately stopping the transmission system, determine whether the voiceprint pattern of the ambient sound matches the preset voiceprint pattern when a determination is made that the one of the control commands is not for immediately stopping the transmission system, and instruct the OHT to perform the move corresponding to the one of the control commands through the control circuit portion when a determination is made that the voiceprint pattern matches the preset voiceprint pattern.

Thus, through the construction of the embodiments above, the overhead hoist transport (OHT) of disclosure can be timely controlled, thereby avoid affecting the production efficiency of the production site and reducing personnel security risks. Furthermore, in response to the complex environment in the production site, it is important to provide different ways for controlling OHT so as to increase flexibility.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The disclosure can be more fully understood by reading the following detailed description of the embodiment, with reference made to the accompanying drawings as follows:

FIG. 1 is a schematic side view of an overhead hoist transport according to one embodiment of the present disclosure.

FIG. 2 is a block diagram of the overhead hoist transport in FIG. 1.

FIG. 3 is a flowchart of a voice control method of an overhead hoist transport according to one embodiment of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

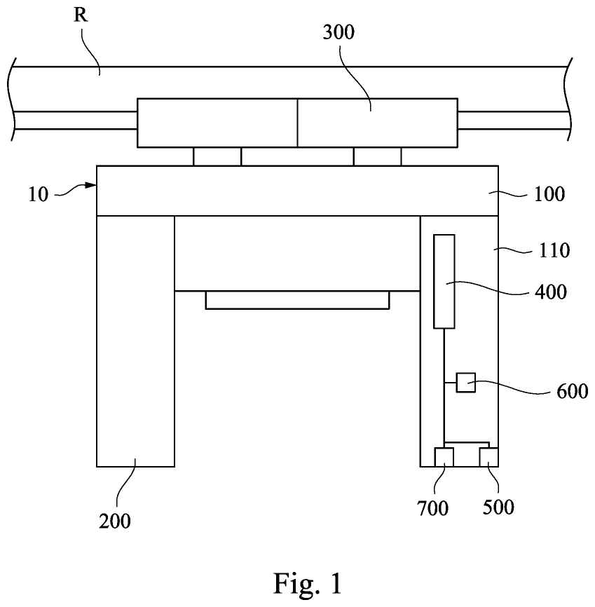

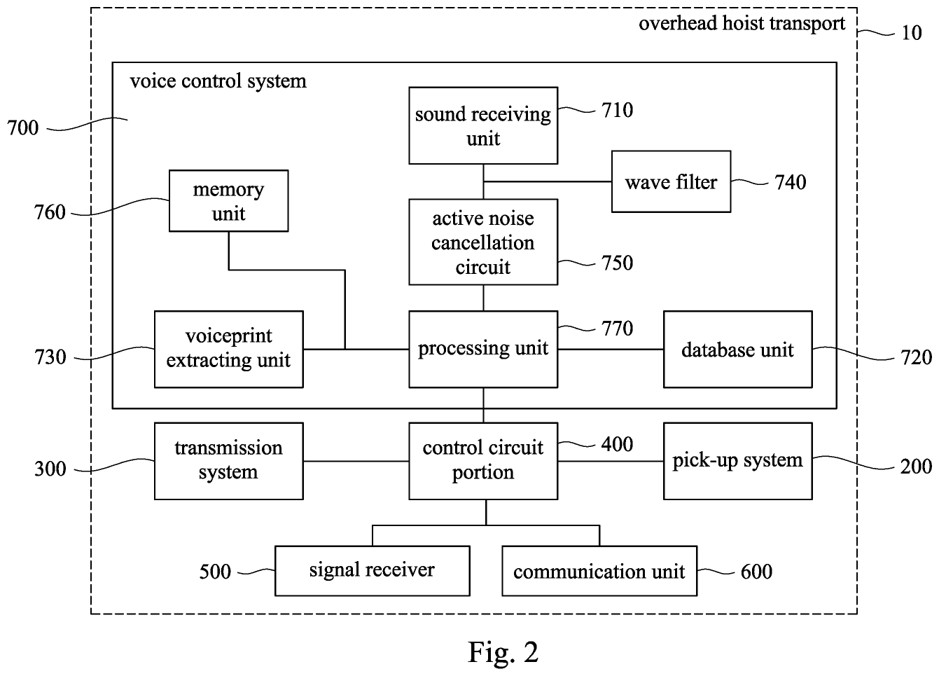

Reference is now made to FIG. 1 and FIG. 2, in which FIG. 1 is a schematic side view of an overhead hoist transport 10 according to one embodiment of the present disclosure, and FIG. 2 is a block diagram of the overhead hoist transport 10 in FIG. 1. As shown in FIG. 1 and FIG. 2, in this embodiment, an overhead hoist transport (OHT) 10 includes a housing 100, a pick-up system 200, a transmission system 300, a control circuit portion 400 and a voice control system 700. The transmission system 300 is disposed on the housing 100 for moving the OHT 10 along a rail R. The pick-up system 200 is disposed on the housing 100 and opposite to the transmission system 300 for reaching downwards to pick up an object (e.g., wafer cassette, not shown in figures) when the OHT 10 is in a stationary state. The control circuit portion 400 is disposed in the housing 100 and electrically connected to the pick-up system 200 and the transmission system 300 for appropriately operating the pickup system and the transmission system 300, respectively. The control circuit portion 400 is stored with control codes. The control codes are readable by the control circuit portion 400 for performing the OHT (including the pick-up system 200 and the transmission system 300) to perform in variety of moves.

The voice control system 700 is arranged on the housing 100, for example, the voice control system 700 is arranged on a front panel 110 of the housing 100. The voice control system 700 includes a sound receiving unit 710, a database unit 720, a voiceprint extracting unit 730 and a processing unit 770. The sound receiving unit 710 is disposed on the housing 100 for receiving an ambient sound. The database unit 720 is disposed in the housing 100 and stored with control commands and preset voiceprint patterns of authorized users. Each of the control commands is corresponded to the control codes described above. The voiceprint extracting unit 730 is disposed in the housing 100 for extracting a voiceprint pattern from the ambient sound. The processing unit 770 is electrically connected to the sound receiving unit 710, the database unit 720, the voiceprint extracting unit 730 and the control circuit portion 400 for appropriately operating the sound receiving unit 710, the database unit 720 and the voiceprint extracting unit 730, and controlling the pickup system and the transmission system 300 through the control circuit portion 400. In the embodiment, the processing unit 770 can perform according to a voice control method of OHT 10 in emergency described below.

Specifically, in the embodiment, the voice control system 700 further includes a wave filter 740. The wave filter 740 is electrically connected to the processing unit 770 and the sound receiving unit 710 for performing an audio filtering process to the ambient sound. For example, the wave filter 740 is a bandpass filter which is an electronic filter that can pass frequency signals within a certain range and prevent other frequency signals (e.g., noise or unhuman voice etc.) from passing through. It only allows frequency signals (e.g., human voice 100 Hz to 1.5 KHz) within a certain range to pass through, while blocking frequency signals below and above this range.

Thus, the wave filter 740 (e.g., bandpass filter) performs an audio filtering process to the ambient sound for passing frequency signals within the certain range and preventing other frequency signals from passing through, however, the present disclosure is not limited thereto.

In this embodiment, the sound receiving unit 710 and the wave filter 740 are arranged separately, however, the present disclosure is not limited thereto, in another embodiment, the wave filter 740 may also be inbuilt in the sound receiving unit 710.

Also, the voice control system 700 further includes an active noise cancellation circuit 750. The active noise cancellation circuit 750 is electrically connected to the processing unit 770 and the sound receiving unit 710 for performing an active noise-reduction process to the ambient sound when an intensity of the ambient sound is greater than a preset threshold (e.g., 60 dB to 80 dB). When the active noise cancellation circuit 750 performs the active noise-reduction process, the active noise cancellation circuit 750 neutralizes sound waves of the ambient sound by reducing harmful environmental noise. However, since the active noise-reduction process is well known in the related field, the active noise-reduction process is not described again herein. In the embodiment, the preset threshold can be simulated or collected in advance, and then recorded in the database unit 720 or other similar hardware.

In this embodiment, the active noise cancellation circuit 750 and the processing unit 770 are arranged separately, however, the present disclosure is not limited thereto, in another embodiment, the active noise cancellation circuit 750 may also be inbuilt inside the processing unit 770.

In addition, the voice control system 700 further includes a memory unit 760. The memory unit 760 is disposed in the housing 100 of the OHT 10, electrically connected to the processing unit 770 and stored with a serial number which represents to this OHT 10.

Furthermore, the OHT 10 further includes a signal receiver 500 and a communication unit 600. The signal receiver 500 is disposed on the housing 100 of the OHT 10 and electrically connected to the control circuit portion 400 for receiving signals from a remote controller through the atmosphere (i.e., air). Thus, when the signal receiver 500 receives and passes one of the control codes from the remote controller to the control circuit portion 400, the control circuit portion 400 controls the OHT 10 (e.g., the pick-up system 200 and the transmission system 300) according to the corresponding control code. The communication unit 600 is disposed in the housing 100 of the OHT 10 and electrically connected to the control circuit portion 400 and the processing unit 770 through the control circuit portion 400, and the communication unit 600 is able to receive wireless signals from a server through networks (e.g., Internet). Hence, in response to the complex environment in the production site, the voice control system 700 provided for controlling OHT 10 can increase flexibility in OHT 10 control ways.

In the embodiment, the sound receiving unit 710 is, for example, a microphone; the database unit 720 is, for example, a storage device such as non-volatile memory express (NVMe) storage devices, solid state drives (SSD) and hard disk drives (HDD); the voiceprint extracting unit 730 is for example, a voiceprint pattern analysis module capable of extracting a voiceprint pattern from the ambient sound; the memory unit 760 is, for example, a read-only memory (ROM) or a flash memory; the signal receiver 500 is, for example, an infrared (IR) signal receiver, and the communication unit 600 is, for example, a WiFi communication unit, however, the signal receiver 500 and the communication unit 600 are not limited to various communication formats; and the processing unit 770 is, for example, a central processing unit (CPU), a microcontroller unit or a single-chip device having programs. However, the present disclosure is not limited thereto. Also, the aforementioned control commands (i.e., control codes) respectively are expressed as “return”, “turn left”, “go straight”, “turn right”, “go forward”, “go back”, “step forward”, “step back”, “stop”, “exit”, “return home”, “moving left, straight or right on forked paths”, “driving wheel rotated forward and reverse”, “driving wheel rotated forward by one unit”, “driving wheel rotated reverse by one unit”, “terminate all actions and stay idle”, and “quit operation program”, however, the present disclosure is not limited thereto.

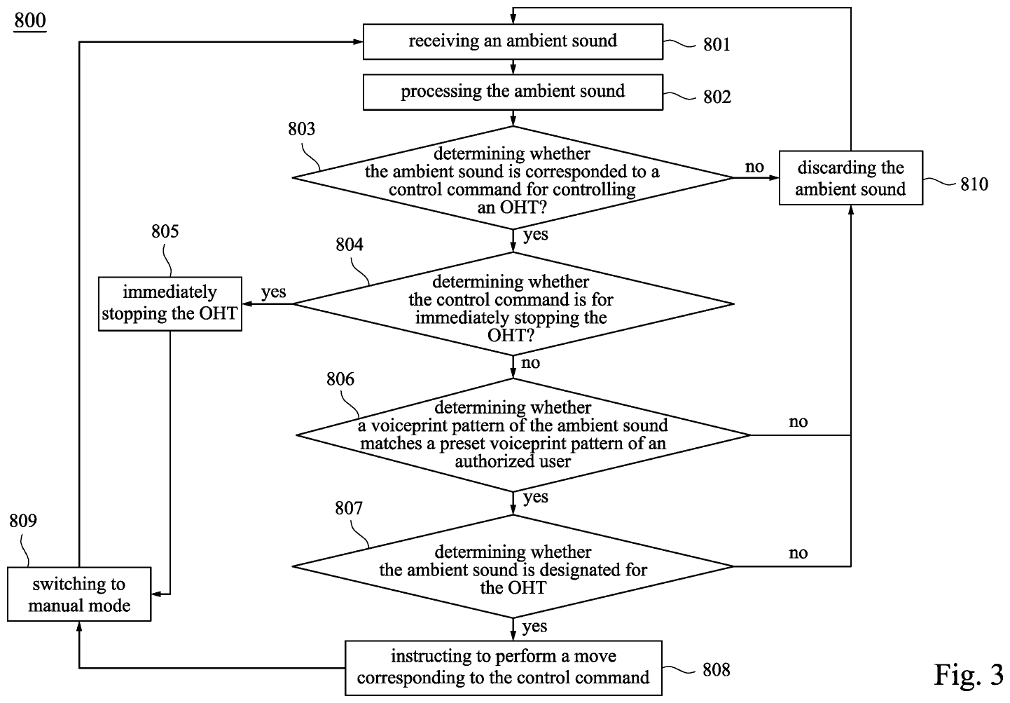

FIG. 3 is a flowchart of a voice control method 800 of OHT 10 in emergency according to one embodiment of the present disclosure. As shown in FIG. 2 and FIG. 3, in this embodiment, the voice control method 800 of OHT 10 in emergency includes step 801 to step 810 as follows. In step 801, an ambient sound is received. In step 802, the ambient sound is processed. In step 803, a determination is made as whether the ambient sound is corresponded to a control command for controlling an OHT 10, if yes, go to step 804, otherwise, go to step 810. In step 804, a determination is made as whether the control command is for immediately stopping the OHT 10, if yes, go to step 805, otherwise, go to step 806. In step 805, the OHT 10 is immediately stopped, then go to step 809. In step 806, a determination is made as whether a voiceprint pattern of the ambient sound matches a preset voiceprint pattern of an authorized user, if yes, go to step 807, otherwise, back to step 810. In step 807, a determination is made as whether the ambient sound is designated for the OHT 10. In step 808, the OHT 10 is instructed to perform a move corresponding to the control command, then go to step 809. In step 809, the OHT 10 is switched into a manual mode, then back to step 801. In step 810, the ambient sound is discarded.

Specifically, step 802 further includes a detailed step as follows. An audio filtering process is performed to the ambient sound For example, the wave filter 740 (e.g., bandpass filter) performs the audio filtering process to the ambient sound, however, the present disclosure is not limited thereto.

In the embodiment, the audio filtering process performed to the ambient sound further includes a detailed step as follows. An environmental noise part and a non-human vocal part in a frequency range of the ambient sound are blocked so as to enable a main part in the frequency range of the ambient sound to be passed through only. For example, the wave filter 740 blocks the environmental noise part and the non-human vocal part (below 100 Hz and over 1.5 KHz) in the frequency range of the ambient sound, and enables the main part of the ambient sound to be passed through only.

Furthermore, the step 802 further includes detailed steps as follows. A determination is made as whether an intensity of the ambient sound is greater than a preset threshold, if yes, an active noise-reduction process is performed to the ambient sound after the audio filtering process is performed to the ambient sound, otherwise, the ambient sound is discarded. In this embodiment, when the active noise cancellation circuit 750 performs the active noise-reduction process, the active noise cancellation circuit 750 neutralizes sound waves of the ambient sound by reducing harmful environmental noise.

Step 803 further includes detailed steps as follows. The ambient sound is converted into a text message. Next, the text message is identified to determine whether the text message matches one of the control commands in the database unit 720. More specifically, in this embodiment, after the ambient sound is converted into the text message, the processing unit 770 matches the text message with the control commands, and decides whether the text message matches any of the control commands in the database unit 720.

For example, in this embodiment, a small Al model of speech recognition and voiceprint recognition can be built by an automatic speech recognition (ASR) technology (e.g., Transformer Architecture) through the networks. Thus, the processing unit 770 converts the ambient sound into the text message with the aforementioned small Al model. However, since the ASR technology is well known in the related field, the introductions for ASR are not described again herein.

In step 805 of the embodiment, if the text message matched with the control command is for immediately stopping the OHT 10, the processing unit 770 sends said control command to the control circuit portion 400 so that the control circuit portion 400 instructs the transmission system 300 to immediately stop the OHT 10 by the control code corresponding to said control command.

Also, when a determination is made that the control command is for immediately stopping the OHT 10, step 805 further includes detailed steps as follows. A brake (not shown in figures) of the OHT 10 is immediately activated to stop the OHT 10 on the rail, and the OHT 10 is instructed to terminate all actions and stay idle.

It is note, when the OHT 10 is in an emergency situation, personnel at the site says the word “immediately stop”, the processing unit 770 instruct the control circuit portion 400 to stop the transmission system 300 of the OHT 10 on the rail R (FIG. 1) without requiring to preliminarily confirm the permissions of the personnel.

However, the present disclosure is not limited thereto, in another embodiment, when a number of OHTs 10 are served in the production site, and a determination is made that the ambient sound received from personnel is the word “immediately stopping”, therefore, all of the OHTs 10 are instructed to be immediately stopped without requesting which OHT 10 to be stopped from control command.

In specific, the step 806 in the embodiment further includes detailed steps as follows. A voiceprint pattern is extracted from the ambient sound. The voiceprint pattern of the ambient sound is identified to determine whether the voiceprint pattern of the ambient sound matches the preset voiceprint pattern registered in the database unit 720.

More specifically, in this embodiment, the step 807 in the embodiment further includes detailed steps as follows. The ambient sound is converted into a text message having characters arranged together in a row. The text message is identified to determine whether at least one part of the text message matches the aforementioned serial number representing to the OHT 10. Thus, when a determination is made that one part of the text message matches the aforementioned serial number representing to the OHT 10, the OHT 10 designated by the corresponding control command is only instructed to perform the move corresponding to the control command. For example, if the characters of the text message are “trolley”, “zero” to “nine”, “ten”, “hundred”, “thousand”, and “number”, an OHT 10 having a serial number “trolley one hundred and nine” can be designated. However, the present disclosure is not limited thereto.

in the embodiment, the step 808 further includes detailed steps as follows. Only the OHT 10 designated by the control command is instructed by the control command to perform the move corresponding to the control command as long as the OHT 10 is designated by the control command and the voiceprint pattern of the ambient sound is identical to the preset voiceprint pattern of the authorized user.

In the embodiment, the step 809 further includes detailed steps as follows. After the OHT 10 is finished performing its move according to the control command, the OHT 10 is mandatorily switched into a manual mode, so that the personnel can operate the OHT 10 at the site for troubleshooting.

However, in another embodiment, based on some requirement or restriction, the step 802, the step 807 and step 809 can be omitted in this disclosure.

Thus, through the construction of the embodiments above, the overhead hoist transport of the present disclosure can be timely controlled, thereby avoid affecting the production efficiency of the production site and reducing personnel security risks. Furthermore, in response to the complex environment in the production site, it is important to provide different ways for controlling overhead hoist transport so as to increase flexibility.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure covers modifications and variations of this disclosure provided they fall within the scope of the following claims and their equivalents.

What is claimed is:

1. A voice control method of an overhead hoist transport (OHT), comprising:
(a) receiving an ambient sound;
(b) determining whether the ambient sound is corresponded to one of control commands for controlling the OHT;
(c) determining whether the one of the control commands is for immediately stopping the OHT when a determination is made that the ambient sound is corresponded to the one of the control commands for controlling the OHT;
(d) immediately stopping the OHT when a determination is made that the one of the control commands is for immediately stopping the OHT;
(e) determining whether a voiceprint pattern of the ambient sound matches a preset voiceprint pattern of an authorized user when a determination is made that the one of the control commands is not for immediately stopping the OHT; and
(f) instructing the OHT to perform a move corresponding to the one of the control commands when a determination is made that the voiceprint pattern matches the preset voiceprint pattern.

2. The voice control method of the overhead hoist transport (OHT) of claim 1, further comprising:
processing the ambient sound before step (b).

3. The voice control method of the overhead hoist transport (OHT) of claim 2,
wherein the step of processing the ambient sound comprises:
performing an audio filtering process to the ambient sound.

4. The voice control method of the overhead hoist transport (OHT) of claim 3, wherein the step of performing the audio filtering process to the ambient sound comprises:
blocking an environmental noise part and a non-human vocal part in a frequency range of the ambient sound, and enabling a main part in the frequency range of the ambient sound to be passed through only.

5. The voice control method of the overhead hoist transport (OHT) of claim 3, wherein the step of processing the ambient sound comprises:
determining whether an intensity of the ambient sound is greater than a preset threshold; and
when a determination is made that the intensity of the ambient sound is greater than the preset threshold, performing an active noise-reduction process to the ambient sound after performing the audio filtering process to the ambient sound.

6. The voice control method of the overhead hoist transport (OHT) of claim 1, wherein step (d) further comprises:
activating a brake of the OHT for stopping the OHT immediately; and
instructing the OHT to terminate all actions and stay idle.

7. The voice control method of the overhead hoist transport (OHT) of claim 1, wherein step (b) further comprises:
converting the ambient sound into a text message; and
identifying the text message of the ambient sound and determining whether the text message matches one of the control commands stored in a database unit.

8. The voice control method of the overhead hoist transport (OHT) of claim 1, further comprising:
determining whether the one of the control commands is designated for the OHT after step (e); and
when a determination is made that the one of the control commands is designated for the OHT, instructing the OHT designated by the one of the control commands to perform the move corresponding to the one of the control commands.

9. The voice control method of the overhead hoist transport (OHT) of claim 8, wherein the step of determining whether the ambient sound is designated for the OHT comprises:
converting the ambient sound into a text message; and
identifying the text message and determining whether at least one part of the text message matches a serial number of the OHT,
wherein when a determination is made that the at least one part of the text message matches the serial number, only instructing the OHT designated by the one of the control commands to perform the move corresponding to the one of the control commands.

10. The voice control method of the overhead hoist transport (OHT) of claim 1, wherein step (e) further comprises:
extracting the voiceprint pattern from the ambient sound; and
identifying the voiceprint pattern of the ambient sound and determining whether the voiceprint pattern of the ambient sound matches the preset voiceprint pattern registered in a database unit.

11. A voice control system of an overhead hoist transport (OHT), comprising:
a sound receiving unit configured to receive an ambient sound;
a database unit stored with control commands and a preset voiceprint pattern of an authorized user, wherein the control commands are respectively used for controlling the OHT;
a voiceprint extracting unit configured to extract a voiceprint pattern from the ambient sound; and
a processing unit electrically connected to the sound receiving unit, the database unit and the voiceprint extracting unit and configured to:
determine whether the ambient sound is corresponded to one of the control commands for controlling the OHT,
determine whether the one of the control commands is for immediately stopping the OHT when a determination is made that the ambient sound is the one of the control commands for controlling the OHT,
immediately stop the OHT when a determination is made that the one of the control commands is for immediately stopping the OHT,
determine whether the voiceprint pattern of the ambient sound matches the preset voiceprint pattern of the authorized user when a determination is made that the one of the control commands is not for immediately stopping the OHT, and
instruct the OHT to perform a move corresponding to the one of the control commands when a determination is made that the voiceprint pattern matches the preset voiceprint pattern.

12. The voice control system of the overhead hoist transport (OHT) of claim 11, further comprising:
a wave filter electrically connected to the processing unit and the sound receiving unit and configured to perform an audio filtering process to the ambient sound.

13. The voice control system of the overhead hoist transport (OHT) of claim 11, further comprising:
an active noise cancellation circuit electrically connected to the processing unit and the sound receiving unit and configured to perform an active noise-reduction process to the ambient sound when an intensity of the ambient sound is greater than a preset threshold.

14. The voice control system of the overhead hoist transport (OHT) of claim 13, wherein the active noise cancellation circuit is inbuilt in the processing unit.

15. The voice control system of the overhead hoist transport (OHT) of claim 11, further comprising:
a memory unit electrically connected to the processing unit and stored with a serial number of the OHT,
wherein the processing unit is configured to convert the ambient sound into a text message, identify the text message and determine whether the text message matches the serial number of the OHT, and only instruct the OHT designated by the one of the control commands to perform the move corresponding to the one of the control commands.

16. An overhead hoist transport (OHT), comprising:
a housing;
a pick-up system disposed on the housing for picking up an object;
a transmission system disposed on the housing for moving along a rail;
a control circuit portion disposed in the housing, and electrically connected to the pick-up system and the transmission system for controlling the pick-up system and the transmission system; and
a voice control system comprising a sound receiving unit, a database unit, a voiceprint extracting unit and a processing unit, the sound receiving unit that is disposed on the housing for receiving an ambient sound, the database unit that is disposed in the housing and stored with control commands and a preset voiceprint pattern of an authorized user, and the control commands are respectively used for controlling the OHT, the voiceprint extracting unit that is disposed in the housing for extracting a voiceprint pattern from the ambient sound, the processing unit that is electrically connected to the sound receiving unit, the database unit, the voiceprint extracting unit and the control circuit portion, wherein the processing unit is configured to:
determine whether the ambient sound is corresponded to one of the control commands for controlling the OHT,
determine whether the one of the control commands is for immediately stopping the transmission system when a determination is made that the ambient sound is corresponded to the one of the control commands for controlling the OHT,
immediately stop the transmission system when a determination is made that the one of the control commands is for immediately stopping the transmission system,
determine whether the voiceprint pattern of the ambient sound matches the preset voiceprint pattern when a determination is made that the one of the control commands is not for immediately stopping the transmission system, and
instruct the OHT to perform a move corresponding to the one of the control commands through the control circuit portion when a determination is made that the voiceprint pattern matches the preset voiceprint pattern.

17. The overhead hoist transport (OHT) of claim 16, wherein the voice control system further comprising:
a wave filter electrically connected to the processing unit and the sound receiving unit for performing an audio filtering process to the ambient sound.

18. The overhead hoist transport (OHT) of claim 16, wherein the voice control system further comprising:
an active noise cancellation circuit electrically connected to the processing unit and the sound receiving unit for performing an active noise-reduction process to the ambient sound when an intensity of the ambient sound is greater than a preset threshold.

19. The overhead hoist transport (OHT) of claim 18, wherein the active noise cancellation circuit is inbuilt in the processing unit.

20. The overhead hoist transport (OHT) of claim 16, wherein the voice control system further comprising:
a memory unit disposed in the housing of the OHT, and electrically connected to the processing unit and stored with a serial number of the OHT,
wherein the processing unit is configured to convert the ambient sound into a text message, identify the text message and determine whether the text message matches the serial number, and only instruct the OHT designated by the one of the control commands to perform a move corresponding to the one of the control commands.
